(19) United States
(12) Patent Application Publication
(10) Pub. No.: US 2025/0351710 A1
(43) Pub. Date: Nov. 13, 2025

(54) DISPLAY DEVICE

(71) Applicant: Samsung Display Co., LTD., Yongin-si (KR)

(72) Inventors: JUNG-WOO LEE, Yongin-si (KR); Su Jeong KIM, Yongin-si (KR); WOOYOUNG KIM, Yongin-si (KR); EUNBEE LEE, Yongin-si (KR); Jin Hyeong LEE, Yongin-si (KR)

(21) Appl. No.: 19/020,007

(22) Filed: Jan. 14, 2025

(30) Foreign Application Priority Data
May 13, 2024 (KR) 10-2024-0062798

(51) Int. Cl. H10K 59/80; H10K 59/126; H10K 59/40

(52) U.S. Cl. CPC H10K 59/878; H10K 59/126; H10K 59/40

(57) ABSTRACT

A display device includes a substrate, a first electrode disposed on the substrate, a pixel defining layer having a pixel opening defined on the first electrode, a light-emitting layer disposed in the pixel opening, a second electrode disposed on the light-emitting layer, an encapsulation layer disposed on the second electrode, a sensing electrode portion and a reflective layer disposed on the encapsulating layer, a first light-blocking layer overlapping the sensing electrode portion, and a second light-blocking layer overlapping the reflective layer, where the reflective layer includes a plurality of concave portions disposed in an area overlapping the second light-blocking layer.

This application claims priority to Korean Patent Application No. 10-2024-0062798, filed on May 13, 2024, and all the benefits accruing therefrom under 35 U.S.C. § 119, the content of which in its entirety is herein incorporated by reference.

### BACKGROUND

### (a) Field

The disclosure relates to a display device, and more specifically, to a display device with improved light efficiency.

### (b) Description of the Related Art

A display device is a device that displays a screen and includes a liquid crystal display (“LCD”) and an organic light-emitting diode (“OLED”) display. These display devices are used in various electronic devices such as mobile phones, navigation devices, digital cameras, electronic books, portable game consoles, and various terminals.

### SUMMARY

Embodiments are intended to provide a display device with improved display quality by improving light efficiency.

A display device in an embodiment includes a substrate, a first electrode disposed on the substrate, a pixel defining layer in which a pixel opening is defined on the first electrode, a light-emitting layer disposed in the pixel opening, a second electrode disposed on the light-emitting layer, an encapsulation layer disposed on the second electrode, a sensing electrode portion and a reflective layer disposed on the encapsulating layer, a first light-blocking layer overlapping the sensing electrode portion, and a second light-blocking layer overlapping the reflective layer, where the reflective layer includes a plurality of concave portions disposed in an area overlapping the second light-blocking layer.

In an embodiment, the display device may further include a sensing insulating layer disposed between the reflective layer and the encapsulation layer, and the sensing insulating layer may include a plurality of recess areas corresponding to the plurality of concave portions.

In an embodiment, the reflective layer may contact an upper surface of the sensing insulating layer.

In an embodiment, the sensing electrode portion may include a first electrode layer and a second electrode layer disposed in different conductive layers, and the sensing insulating layer may include a portion disposed between the first electrode layer and the second electrode layer.

In an embodiment, at least some of the plurality of concave portions may be circular shape in a plan view.

In an embodiment, at least some of the plurality of concave portions may be an oval shape with a major axis in a plan view.

In an embodiment, directions of major axes of the plurality of concave portions may be the same as each other.

In an embodiment, directions of major axes of two or more of the plurality of concave portions may be different from each other.

In an embodiment, at least some of the plurality of concave portions may be polygonal shape in a plan view.

In an embodiment, distances between centers of concave portions next to each other among the plurality of concave portions may be constant.

In an embodiment, for at least some of the plurality of concave portions, the distances between centers of concave portions next to each other among the plurality of concave portions may not be constant.

In an embodiment, at least some of the plurality of concave portions may be disposed in an outer area of the reflective layer.

In an embodiment, at least some of the plurality of concave portions may be disposed in an inner area of the reflective layer.

In an embodiment, a concave portion of the plurality of concave portions may have a curve in a cross-sectional view.

The display device in an embodiment includes a substrate, a first electrode disposed on the substrate, a pixel defining film in which a pixel opening overlapping the first electrode is defined, a light-emitting layer disposed in the pixel opening, a second electrode disposed above the light-emitting layer, the encapsulation layer disposed above the second electrode, a sensing electrode portion and a reflective layer disposed above the encapsulation layer, a first blocking layer overlapping the sensing electrode portion, and a second blocking layer overlapping the reflective layer, where the reflective layer includes an uneven portion and a flat portion in the area overlapping the second blocking layer.

In an embodiment, the uneven portion may include a plurality of concave portions.

In an embodiment, the uneven portion may be disposed in an outer area of the reflective layer.

In an embodiment, the uneven portion may be disposed more in an inner area of the reflective layer.

In an embodiment, a planar shape of the plurality of concave portions may be at least one of a circular shape, an oval shape, a triangle shape, a square shape, or a pentagon shape with a center.

In an embodiment, the distances between centers of concave portions next to each other among the plurality of concave portions may be constant.

By embodiments, the display device with improved display quality by improving light efficiency may be provided.

### BRIEF DESCRIPTION OF THE DRAWINGS

The above and other exemplary embodiments, advantages and features of this disclosure will become more apparent by describing in further detail exemplary embodiments thereof with reference to the accompanying drawings, in which:

FIG. 1 is a schematic perspective view illustrating an embodiment of a use state of a display device.

FIG. 2 is an exploded perspective view of an embodiment of a display device.

FIG. 3 is a block diagram of an embodiment of a display device.

FIG. 4 is a schematic plan view of an embodiment of a sensing electrode in a display panel.

FIG. 5 is a schematic plan view showing an embodiment of a plurality of pixels in a display panel.

FIG. 6 is a cross-sectional view illustrating an embodiment of a portion of a display area in a display panel taken along line A1-A2 of FIG. 5.

FIG. 7 is a cross-sectional view showing a portion of FIG. 6 taken along line B1-B2 of FIG. 8.

FIGS. 8, 9, 10, 11, 12, 13, 14, and 15 are plan views showing an embodiment of a portion of a pixel.

### DETAILED DESCRIPTION

Hereinafter, with reference to the attached drawings, various embodiments of the disclosure will be described in detail so that those skilled in the art may easily implement the disclosure. The disclosure may be implemented in many different forms and is not limited to the embodiments described herein.

In order to clearly explain the disclosure, parts that are not relevant to the description are omitted, and identical or similar components are assigned the same reference numerals throughout the specification.

In addition, the size and thickness of each component shown in the drawings are arbitrarily shown for convenience of explanation, so the disclosure is not necessarily limited to that which is shown. In the drawings, the thicknesses are enlarged to clearly express various layers and areas. And in the drawings, for convenience of explanation, the thicknesses of some layers and regions are exaggerated.

Additionally, when a part of a layer, membrane, region, or plate is said to be “above” or “on” another part, this includes not only cases where it is “directly above” another part, but also cases where there is another part in between. In contrast, when an element is referred to as being “directly on” another element, there are no intervening elements present. In addition, being “above” or “on” a reference part means being disposed above or below the reference part, and does not necessarily mean being disposed “above” or “on” it in the direction opposite to gravity.

In addition, throughout the specification, when a part is said to “include” a certain component, this means that it may further include other components rather than excluding other components, unless specifically stated to the contrary.

In addition, throughout the specification, when reference is made to “in a plan view,” this means when the target part is viewed from above, and when reference is made to “in a cross-section,” this means when a cross-section of the target portion is cut vertically and viewed from the side.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term such as “about” can mean within one or more standard deviations, or within +30%, 20%, 10%, 5% of the stated value, for example.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein. An embodiment of a display device may be applied to various electronic devices. An embodiment of an electronic device may include the display device, and may further include modules or devices having additional functions other than the display device.

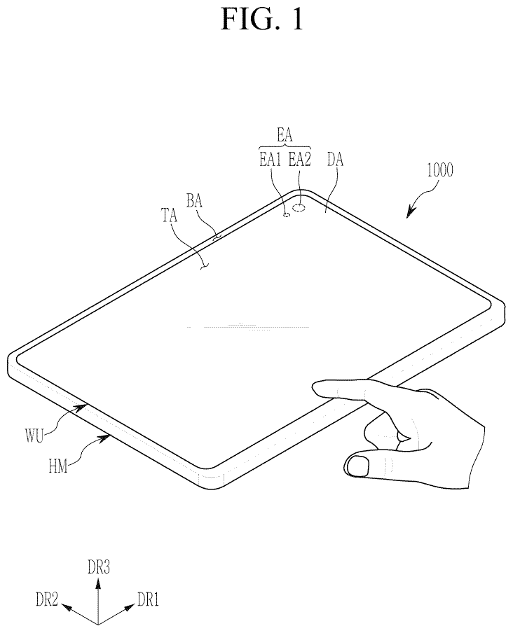

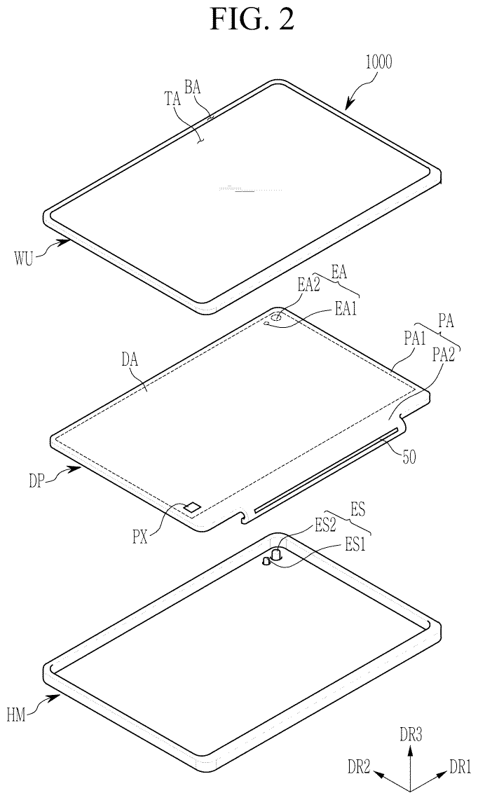

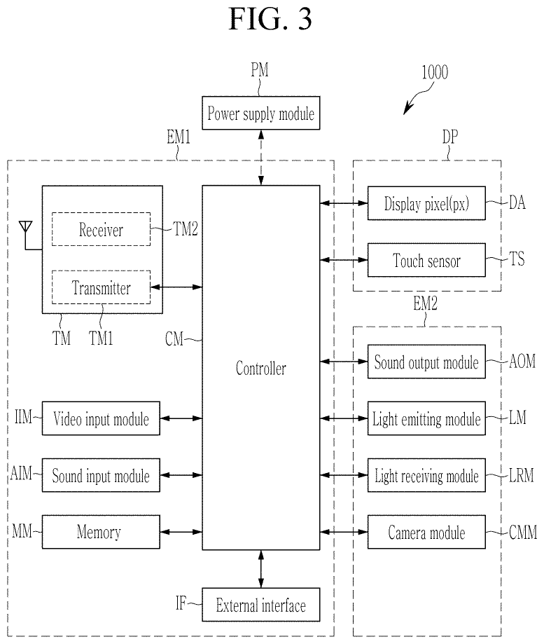

Hereinafter, a schematic structure of the display device will be described through FIGS. 1 to 3. FIG. 1 is a schematic perspective view showing an embodiment of a use state of a display device, FIG. 2 is an exploded perspective view of an embodiment of a display device, and FIG. 3 is a block diagram of an embodiment of a display device.

Referring to FIG. 1, the display device 1000 in an embodiment is a device that displays video or still images, and may be used as a display screen for various products such as mobile phones, smartphones, tablet personal computers (“PCs”), mobile communication terminals, electronic notepads, e-books, portable multimedia players, navigation systems, ultra-mobile PCs, as well as for televisions, laptops, monitors, billboards, and the Internet of Things (“IoT”). Additionally, the display device 1000 in an embodiment may be used in wearable devices such as smart watches, watch phones, glasses-type displays, and head mounted displays (“HMD”). Additionally, the display device 1000 in an embodiment may be used as an automobile's dashboard, a center information display (“CID”) disposed on the automobile's center fascia or dashboard, a room mirror display replacing the automobile's side mirror, and a display placed on the back of the front seats for rear seat entertainment in the automobile. FIG. 1 shows the display device 1000 being used as a tablet PC for convenience of explanation.

The display device 1000 may display an image in the third direction DR3 on a display surface parallel to each of the first direction DR1 and the second direction DR2. The display surface on which the image is displayed may correspond to the front surface of the display device 1000 and the front surface of the cover window WU. Images may include static images as well as dynamic images.

In this embodiment, the front (or top) and back (or bottom) surfaces of each member are defined based on the direction in which the image is displayed. The front and back surfaces are opposed to each other in the third direction DR3, and the normal directions of each of the front and back surfaces may be parallel to the third direction DR3. The separation distance between the front and back surfaces in the third direction DR3 may correspond to the thickness of the display panel in the third direction DR3.

The display device 1000 in an embodiment may detect a user's input (refer to the hand in FIG. 1) applied from the outside. The user's input may include various types of external inputs, such as parts of the user's body, light, heat, or pressure. In an embodiment, the user's input is shown with the user's hand applied to the front. However, the disclosure is not limited to this. User input may be provided in various forms. Additionally, the display device 1000 may detect a user's input applied to the side or back of the display device 1000 depending on the structure of the display device 1000.

Referring to FIGS. 1 and 2, the display device 1000 may include a cover window WU, a housing HM, a display panel DP, and an optical element ES. In an embodiment, the cover window WU and the housing HM may be combined to configure the exterior of the display device 1000.

The cover window WU may include an insulating panel. In an embodiment, the cover window WU may include or consist of glass, plastic, or any combinations thereof.

The front of the cover window WU may define the front of the display device 1000. The transmission region TA may be an optically transparent area. In an embodiment, the transmission region TA may be an area with visible light transmittance of about 90% or more.

The blocking region BA may define the shape of the transmission region TA. The blocking region BA is next (adjacent) to the transmission region TA and may surround the transmission region TA. The blocking region BA may be an area with relatively low light transmittance compared to the transmission region TA. The blocking region BA may include an opaque material that blocks light. The blocking region BA may have a predetermined color. The blocking region BA may be defined by a bezel layer provided separately from the transparent substrate defining the transmission region (hereinafter, also referred to as a transparent area) TA, or may be defined by an ink layer formed by inserting or coloring the transparent substrate.

The display panel DP may include a front surface including a display area DA and a non-display area PA. The display area DA may be an area where pixels operate according to electrical signals and emit light. The non-display area PA of the display panel DP may include the driver 50.

In an embodiment, the display area DA is an area where an image is displayed including a pixel, and at the same time, it may be an area where an external input is sensed by having a touch sensor disposed above the pixel in the third direction DR3.

The transmission area TA of the cover window WU may at least partially overlap the display area DA of the display panel DP. In an embodiment, the transmission area TA may overlap the entirety of the surface of the display area DA or may overlap at least a portion of the display area DA, for example. Accordingly, the user may view the image through the transmission region TA or provide external input based on the image. However, the disclosure is not limited to this. In an embodiment, within the display area DA, an area where an image is displayed and an area where an external input is detected may be separated from each other, for example.

The non-display area PA of the display panel DP may at least partially overlap the blocking region BA of the cover window WU. The non-display area PA may be an area covered by the blocking region BA. The non-display area PA is next (adjacent) to the display area DA and may surround the display area DA. An image is not displayed in the non-display area PA, and a driving circuit or driving wiring for driving the display area DA may be disposed. The non-display area PA may include a first peripheral area PA1 disposed outside the display area DA and a second peripheral area PA2 including the driver 50, connection wiring, and a bending area. In the embodiment of FIG. 2, the first peripheral area PA1 is disposed on the third side of the display area DA, and the second peripheral area PA2 is disposed on the remaining side of the display area DA.

In an embodiment, the display panel DP may be assembled in a flat state with the display area DA and the non-display area PA facing the cover window WU. However, the disclosure is not limited to this. A portion of the non-display area PA of the display panel DP may be curved. At this time, part of the non-display area PA is directed toward the rear of the display device 1000, so that the blocking region BA visible on the front of the display device 1000 may be reduced, and in FIG. 2, the second peripheral area PA2 may be bent and placed on the back of the display area DA and then assembled.

Additionally, the display panel DP may include a component area EA, and specifically, a first component area EA1 and a second component area EA2. The first component area EA1 and the second component area EA2 may be at least partially surrounded by the display area DA. The first component area EA1 and the second component area EA2 are shown spaced apart from each other, but are not limited to this and may be at least partially connected. The first component area EA1 and the second component area EA2 may be areas where components that use infrared light, visible light, or sound are placed below them.

The display area DA is formed with a plurality of light-emitting diodes and a plurality of pixel circuit units that generate and transmit a light-emitting current to each of the plurality of light-emitting diodes. Here, one light-emitting diode and one pixel circuit part are referred to as a pixel PX. In the display area DA, one pixel circuit unit and one light-emitting diode are formed in a one-to-one arrangement.

The first component area EA1 may include a transparent portion through which light and/or sound may transmit and a display portion including a plurality of pixels. The transmission portion is disposed between pixels next to each other, and consists of a layer through which light and/or sound may transmit. The transmitting portion may be disposed between pixels next to each other, and depending on the embodiment, a layer that does not transmit light, such as a light-blocking layer, may overlap the first component area EA1. The number of pixels per unit area (also referred to as resolution) included in the display area DA, referred to as normal pixels, may be the same as the number of pixels per unit area included in the first component area EA1, referred to as first component pixels.

The second component region EA2 includes a region composed of a transparent layer that allows light to pass through (also referred to as a light-transmitting area), where neither a conductive layer nor a semiconductor layer is disposed, and this light-transmitting area may have a structure that does not block light by defining apertures that overlap the position corresponding to the second component area EA2 and include or consist of layers with a shading material, e.g., a pixel defining layer and/or a light-blocking layer. The number of pixels per unit area of the pixels included in the second component area EA2 (hereinafter also referred to as second component pixels) may be smaller than the number of pixels per unit area of the normal pixels included in the display area DA. As a result, the resolution of the second component pixel may be lower than that of the normal pixel.

Referring to FIGS. 1, 2, and 3, the display panel DP may include a display area DA including display pixels and a touch sensor TS. The display panel DP includes pixels that generate images and may be visible to the user from the outside through the transmission area TA. Additionally, the touch sensor TS may be disposed at the top of the pixel and may detect an external input applied from outside. The touch sensor TS may detect an external input provided to the cover window WU.

Referring back to FIG. 2, the second peripheral area PA2 may include a bending portion. The display area DA and the first peripheral area PA1 may have a flat state substantially parallel to the plane defined by the first direction DR1 and the second direction DR2, and one side of the second peripheral area PA2 may be extended from a flat state, pass through a bending portion, and then be in a flat state again. At least a portion of the second peripheral area PA2 may be bent and assembled to be disposed on the rear side of the display area DA. When at least a portion of the second peripheral area PA2 is assembled, it overlaps the display area DA in a plan view, so the blocking region BA of the display device 1000 may be reduced. However, the disclosure is not limited to this. In an embodiment, the second peripheral area PA2 may not be bent, for example.

The driver 50 may be disposed (e.g., mounted) on the second peripheral area PA2, on the bending part, or disposed on one of opposite sides of the bending part. The driver 50 may be provided in the form of a chip.

The driver 50 is electrically connected to the display area DA and may transmit an electrical signal to the display area DA. In an embodiment, the driver 50 may provide data signals to the pixels PX arranged in the display area DA, for example. In an alternative embodiment, the driver 50 may include a touch driving circuit and may be electrically connected to the touch sensor TS disposed in the display area DA. The driver 50 may include various circuits in addition to the circuits described above or may be designed to provide various electrical signals to the display area DA.

The display device 1000 may have a pad portion disposed at the end of the second peripheral area PA2, and this pad portion may be electrically connected to a flexible printed circuit board (“FPCB”) that includes a driving chip. Here, the driving chip disposed on the flexible printed circuit board may include various driving circuits for driving the display device 1000 or a connector for power supply. Depending on the embodiment, a rigid printed circuit board (“PCB”) may be used instead of a flexible printed circuit board.

The optical element ES may be disposed below the display panel DP. The optical element ES may include a first optical element ES1 overlapping the first component area EA1 and a second optical element ES2 overlapping the second component area EA2.

The first optical element ES1 may be an electronic element that uses light or sound. In an embodiment, the first optical element ES1 may be a sensor that receives and utilizes light, such as an infrared sensor, a sensor that outputs and detects light or sound to measure distance or recognize fingerprints, a relatively small lamp that emits light, or a speaker that outputs sound, for example. In the case of electronic elements that use light, it goes without saying that light in various wavelength bands, such as visible light, infrared light, and ultraviolet light, may be used.

The second optical element ES2 may be at least one of a camera, infrared camera IR camera, dot projector, infrared illuminator, and Time-of-Flight (“ToF”) sensor.

Referring to FIG. 3, the display device 1000 may include a display panel DP, a power supply module PM, a first electronic module EM1, and a second electronic module EM2. The display panel DP, the power supply module PM, the first electronic module EM1, and the second electronic module EM2 may be electrically connected to each other. FIG. 3 illustrates display pixels and a touch sensor TS disposed in the display area DA among the configuration of the display panel DP.

The power supply module PM may supply power desired for the overall operation of the display device 1000. The power supply module PM may include a conventional battery module.

The first electronic module EM1 and the second electronic module EM2 may include various functional modules for operating the display device 1000. The first electronic module EM1 may be disposed (e.g., mounted) directly on the motherboard electrically connected to the display panel DP, or may be disposed (e.g., mounted) on a separate board and electrically connected to the motherboard through a connector (not shown).

The first electronic module EM1 may include a control module CM, a wireless communication module TM, an image input module IIM, an audio input module AIM, a memory MM, and an external interface IF. Some of the modules may not be disposed (e.g., mounted) on the motherboard, but may be electrically connected to the motherboard through a flexible printed circuit board connected thereto.

The control module CM may control the overall operation of the display device 1000. The control module CM may be a microprocessor. In an embodiment, the control module CM activates or deactivates the display panel DP, for example. The control module CM may control other modules, such as an image input module IIM or an audio input module AIM, based on the touch signal received from the display panel DP.

The wireless communication module TM may transmit/receive wireless signals to and from other terminals using a Bluetooth or Wi-Fi line. The wireless communication module TM may transmit/receive voice signals using a general communication line. The wireless communication module TM includes a transmitter TM1 that modulates and transmits a signal to be transmitted, and a receiver TM2 that demodulates the received signal.

The image input module IIM may process video signals and convert them into video data that may be displayed on the display panel DP. The audio input module (also referred to as an acoustic input module) AIM may receive external acoustic signals through a microphone in recording mode, voice recognition mode, etc. and convert them into electrical voice data.

The external interface IF may serve as an interface connected to an external charger, wired/wireless data port, card socket (e.g., memory card, subscriber identity module/user identity module (“SIM/UIM”) card), etc.

The second electronic module EM2 may include an acoustic output module AOM, a light-emitting module LM, a light-receiving module LRM, and a camera module CMM, among others, at least some of which may be disposed on the back of the display panel DP as shown in FIGS. 1 and 2, with optical elements ES.

The optical elements ES may include a light-emitting module LM, a light-receiving module LRM, and a camera module CMM. Additionally, the second electronic module EM2 may be directly disposed (e.g., mounted) on the motherboard, disposed (e.g., mounted) on a separate substrate and electrically connected to the display panel DP through connectors (not shown), or electrically connected to the first electronic module EM1.

The acoustic output module (also referred to as an audio output module) AOM may convert audio data received from the wireless communication module TM or audio data stored in the memory MM and output it to the outside.

The light-emitting module LM may generate and output light. The light-emitting module LM may output infrared rays. In an embodiment, the light-emitting module LM may include an LED device. In an embodiment, a light-receiving module LRM may detect infrared light, for example. The light-receiving module LRM may be activated when infrared rays above a predetermined level are detected, for example. The light-receiving module LRM may include a complementary metal-oxide-semiconductor (“CMOS”) sensor. After the infrared light generated in the light-emitting module LM is output, it is reflected by an external subject (e.g., a user's finger or face), and the reflected infrared light may be incident on the light-receiving module LRM. The camera module CMM may capture external images.

In an embodiment, the optical element ES may additionally include a light detection sensor or a heat detection sensor. The optical element ES may detect an external subject received through the front or provide a sound signal such as voice to the outside through the front. Additionally, the optical element ES may include a plurality of components and is not limited to a particular embodiment.

Again referring to FIG. 2, the housing HM may be combined with the cover window WU. The cover window WU may be disposed on the front of the housing HM. The housing HM may be combined with the cover window WU to provide a predetermined accommodation space. The display panel DP and the optical element ES may be accommodated in a predetermined accommodation space provided between the housing HM and the cover window WU.

The housing HM may include a material with relatively high rigidity. In an embodiment, the housing HM may include a plurality of frames and/or plates including or consisting of glass, plastic, or metal, or any combinations thereof, for example. The housing HM may stably protect the components of the display device 1000 accommodated in the internal space from external shock.

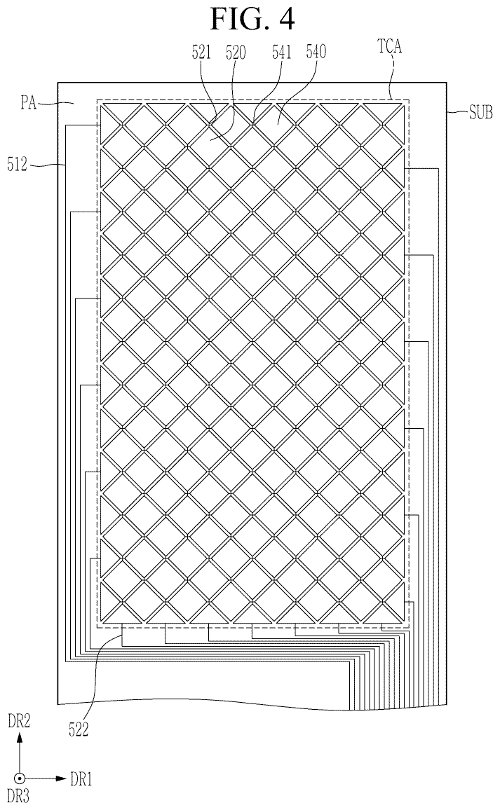

Hereinafter, a sensing electrode in an embodiment will be described with reference to FIG. 4. FIG. 4 is a schematic plan view of an embodiment of a sensing electrode in a display panel.

Referring to FIG. 4, a sensing area TCA including a plurality of sensing electrodes 520 and 540 may be disposed above the display area DA and above the light-emitting diode to recognize a touch. The sensing area TCA may be an area where the touch sensor TS is disposed.

In the non-display area PA, signal lines or voltage lines (e.g., driving voltage lines, low driving voltage lines, etc.) that deliver signals or voltage to the pixels formed in the display area DA may be disposed, and a pad part connected to the signal lines or voltage lines may be disposed. Additionally, a plurality of sensing wires 512 and 522 may be further disposed in the non-display area PA. A plurality of sensing wires 512 and 522 may be connected to a plurality of sensing electrodes 520 and 540.

The sensing area TCA may include a plurality of sensing electrodes 520 and 540. The plurality of sensing electrodes 520 and 540 may include a plurality of first sensing electrodes 520 and a plurality of second sensing electrodes 540 that are electrically separated.

Depending on the embodiment, the plurality of first sensing electrodes 520 may be sensing input electrodes, and the plurality of second sensing electrodes 540 may be sensing output electrodes. However, the disclosure is not limited to this, and the plurality of first sensing electrodes 520 may be sensing output electrodes, and the plurality of second sensing electrodes 540 may be sensing input electrodes.

The plurality of first sensing electrodes 520 and the plurality of second sensing electrodes 540 may be distributed and arranged in a mesh shape so as not to overlap each other in the sensing area TCA. The plurality of first sensing electrodes 520 are arranged along one of the column direction and the row direction (refer to FIG. 4, the second direction DR2), and the plurality of first sensing electrodes 520 are electrically connected to each other by a first sensing electrode connection portion (521; also referred to as a bridge). The plurality of second sensing electrodes 540 are also arranged along a remaining (the other) one of the column direction and the row direction (refer to FIG. 4, the first direction DR1), and the multiple second sensing electrodes 540 are electrically connected to each other by a second sensing electrode connection portion 541.

The plurality of first sensing electrodes 520 and the plurality of second sensing electrodes 540 may be disposed on the same conductive layer. Depending on the embodiment, the plurality of first sensing electrodes 520 and the plurality of second sensing electrodes 540 may be disposed in different conductive layers. According to FIG. 4, the first sensing electrode 520 and the second sensing electrode 540 may have a diamond shape, but are not limited thereto, and depending on the embodiment, may have a polygonal shape such as a square or hexagon, or a circular or oval shape.

The plurality of first sensing electrodes (also referred to as first detection electrodes) 520 and the plurality of second sensing electrodes 540 are shown as an integrated diamond structure, but in reality, one rhombus structure defines an opening, and the linear structure may have an arrangement in a mesh form. At this time, the opening may correspond to an area where the light-emitting diode emits light upward. Additionally, depending on the embodiment, it may have a shape that further includes an extension part to improve the sensitivity of the detection sensor.

The first sensing electrode 520 and the second sensing electrode 540 may include or consist of a transparent conductor or an opaque conductor. In an embodiment, the first sensing electrode 520 and the second sensing electrode 540 may include a transparent conductive oxide (“TCO”), and the TCO may include at least one of indium tin oxide (“ITO”), indium zinc oxide (“IZO”), zinc oxide (ZnO), carbon nanotubes (“CNTs”), and graphene, for example. Additionally, a plurality of openings may be defined in the first sensing electrode 520 and the second sensing electrode 540. The openings defined in the sensing electrodes 520 and 540 serve to allow light emitted from the light-emitting diode to be emitted to the front without interference.

When the first sensing electrode 520 and the second sensing electrode 540 are disposed in the same layer, one of the first sensing electrode connection portion 521 and the second sensing electrode connection portion 541 may be disposed in the same layer as the first sensing electrode 520 and the second sensing electrode 540, and a remining (the other) one may be disposed in a different layer from the first sensing electrode 520 and the second sensing electrode 540. As a result, the plurality of first sensing electrodes 520 and the plurality of second sensing electrodes 540 may be electrically separated. The sensor electrode connection disposed in a different layer may be disposed on the upper or lower layer of the first sensor electrode 520 and the second sensor electrode 540, and in the embodiments described below, the sensor electrode connection is disposed on a lower layer, that is, a layer closer to the substrate, which will be the focus of the description.

A plurality of sensing wires 512 and 522 respectively connected to a plurality of first sensing electrodes 520 and a plurality of second sensing electrodes 540 are disposed in the non-display area PA. The plurality of first sensing wires 512 may be connected to the plurality of second sensing electrodes (also referred to as second detection electrodes) 540 arranged in a first direction DR1, and the plurality of second sensing wires 522 may be connected to the plurality of first sensing electrodes 520 arranged in a second direction DR2.

FIG. 4 shows a mutual-cap type of sensing unit that detects a touch using two sensing electrodes 520 and 540. However, depending on the embodiment, it may be formed as a self-cap type of sensing unit that detects touch using only one sensing electrode.

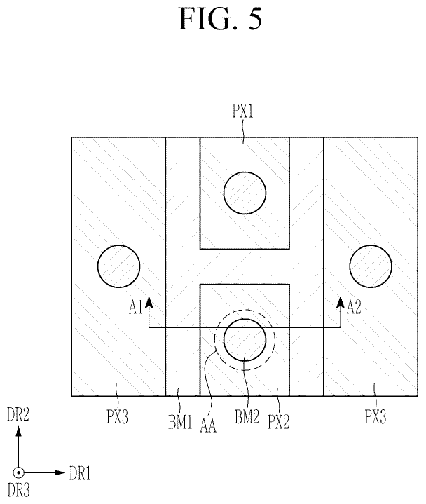

Hereinafter, with reference to FIG. 5, the shapes of the pixels PX1, PX2, and PX3 and the light-blocking layers BM1 and BM2 formed in the display area DA in an embodiment will be described. FIG. 5 is a schematic plan view showing a plurality of pixels.

In FIG. 5, a first pixel PX1, a second pixel PX2, a third pixel PX3, a first light-blocking layer BM1, and a second light-blocking layer BM2 are shown.

The display area DA in an embodiment may include a first pixel PX1 emitting red light, a second pixel PX2 emitting green light, and a third pixel PX3 emitting blue light. In an embodiment, as shown in FIG. 5, in one column, the first pixel PX1 and the second pixel PX2 are alternately arranged along the second direction DR2, and in another column next (adjacent) to this column, the third pixel PX3 may be repeatedly arranged. However, the arrangement form of the pixels is not limited to this arrangement form, and the first pixel PX1, the second pixel PX2, and the third pixel PX3 may be arranged in various forms.

Light-blocking layers BM1 and BM2 in an embodiment may include a first light-blocking layer BM1 and a second light-blocking layer BM2. The first light-blocking layer BM1 may be disposed between the first pixel PX1, the second pixel PX2, and the third pixel PX3. The second light-blocking layer BM2 may overlap the first pixel PX1, the second pixel PX2, or the third pixel PX3. The second light-blocking layer BM2 may be disposed within the boundary of the light-emitting region of the first pixel PX1, the second pixel PX2, or the third pixel PX3. The second light-blocking layer BM2 may have the shape of a circle, oval, or polygonal shape in a plan view. The second light-blocking layer BM2 may absorb external light incident on the light-emitting region and reduce external light reflection.

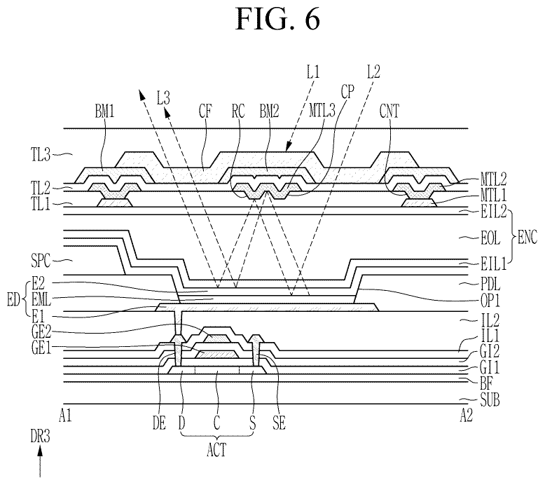

Hereinafter, with reference to FIG. 6, a display device in an embodiment will be described focusing in a cross-sectional view of the display area DA. FIG. 6 is a cross-sectional view illustrating a portion of a display area in a display device.

Referring to FIG. 6, the substrate SUB may include a material with rigid properties such as glass or a flexible material that may be bent such as plastic or polyimide.

A buffer layer BF may be further disposed on the substrate SUB to flatten the surface of the substrate SUB and block penetration of impurity elements. The buffer layer BF may include an inorganic material, e.g., an inorganic insulating material such as a silicon nitride (SiNₓ), a silicon oxide (SiOₓ), or a silicon oxynitride (SiOₓN_{y}). Depending on the embodiment, the buffer layer BF may have a single-layer or multi-layer structure including one or more inorganic insulating materials.

A barrier layer (not shown) may be further disposed on the substrate SUB. At this time, the barrier layer may be disposed between the substrate SUB and the buffer layer BF. The barrier layer may include an inorganic insulating material such as a silicon nitride (SiNₓ), a silicon oxide (SiOₓ), or a silicon oxynitride (SiOₓN_{y}). The barrier layer (not shown) may have a single-layer or multi-layer structure including or consisting of one or more inorganic insulating materials.

The semiconductor layer ACT may be disposed on the substrate SUB. The semiconductor layer ACT may include any one of amorphous silicon, polycrystalline silicon, and an oxide semiconductor. In an embodiment, the semiconductor layer ACT may include low-temperature polysilicon (“LTPS”) or an oxide semiconductor that includes at least one of zinc (Zn), indium (In), gallium (Ga), tin (Sn), and combinations thereof, for example. In an embodiment, the semiconductor layer ACT may include indium-gallium-zinc oxide (“IGZO”), for example. The semiconductor layer ACT may include a channel region C, a source region S, and a drain region D that are divided depending on whether or not the semiconductor layer is doped with impurities. The source region S and drain region D may have conductive characteristics corresponding to the conductors.

The first gate insulating layer GI1 may cover the semiconductor layer ACT and the substrate SUB. The first gate insulating layer GI1 may include an inorganic insulating material such as a silicon nitride (SiNₓ), a silicon oxide (SiOₓ), or a silicon oxynitride (SiOₓN_{y}). The first gate insulating layer GI1 may have a single-layer or multi-layer structure including or consisting of one or more inorganic insulating materials.

The gate electrode GE1 may be disposed on the first gate insulating layer GI1. The gate electrode GE1 may include or consist of a metal or metal alloy such as copper (Cu), molybdenum (Mo), aluminum (Al), silver (Ag), chromium (Cr), tantalum (Ta), and titanium (Ti). The gate electrode GE1 may consist of a single layer or multiple layers. A region of the semiconductor layer ACT that overlaps the gate electrode GE in a plan view may be a channel region C.

The second gate insulating layer GI2 is disposed on the gate electrode GE1. The second gate insulating layer GI2 may include an inorganic insulating material such as a silicon nitride (SiNₓ), a silicon oxide (SiOₓ), or a silicon oxynitride (SiOₓN_{y}). The second gate insulating layer GI2 may have a single-layer or multi-layer structure including one or more inorganic insulating materials.

The capacitor electrode GE2 may be disposed on the second gate insulating layer GI2. The capacitor electrode GE2 may overlap the gate electrode GE1 to form a capacitor.

The first insulating layer IL1 is disposed on the capacitor electrode GE2. The first insulating layer IL1 may include an inorganic insulating material such as silicon nitride (SiNₓ), silicon oxide (SiOₓ), or silicon oxynitride (SiOₓN_{y}). The first insulating layer IL1 may have a single-layer or multi-layer structure including one or more inorganic insulating materials.

The source electrode SE and the drain electrode DE may be disposed on the first insulating layer IL1. The source electrode SE and the drain electrode DE are connected to the source region S and drain region D of the semiconductor layer ACT, respectively, through openings defined in the first insulating layer IL1, the second gate insulating layer GI2, and the first gate insulating layer GI1. Accordingly, the above-described semiconductor layer ACT, gate electrode GE, source electrode SE, and drain electrode DE form one transistor. Depending on the embodiment, the transistor TFT may include only the source and drain regions of the semiconductor layer ACT instead of the source electrode SE and the drain electrode DE.

The source electrode SE and the drain electrode DE may include metals or metal alloys such as aluminum (Al), copper (Cu), silver (Ag), gold (Au), platinum (Pt), palladium (Pd), nickel (Ni), molybdenum (Mo), tungsten (W), titanium (Ti), chromium (Cr), and tantalum (Ta). The source electrode SE and the drain electrode DE may consist of a single layer or multiple layers. In another embodiment, the source electrode SE and the drain electrode DE may consist of a triple layer including an upper layer, a middle layer, and a lower layer, where the upper and lower layers may include or consist of titanium (Ti), and the middle layer may include or consist of aluminum (Al).

The second insulating layer IL2 may be disposed on the source electrode SE and the drain electrode DE. The second insulating layer IL2 covers the source electrode SE and the drain electrode DE. The second insulating layer IL2 is for flattening the surface of a substrate SUB equipped with transistors, and it may be an organic insulation layer, and it may include one or more materials selected from the group including polyimide, polyamide, acrylic resin, benzocyclobutene, and phenol resin.

The first electrode E1 may be disposed on the second insulating layer IL2. The first electrode E1 is also referred to as an anode electrode and may consist of a single layer including or consisting of a transparent conductive oxide layer or a metal material, or a multiple layer including or consisting of these. The transparent conductive oxide layer may include ITO, poly-ITO, IZO, IGZO, and indium tin zinc oxide (“ITZO”). Metal materials may include silver (Ag), molybdenum (Mo), copper (Cu), gold (Au), and aluminum (Al).

The first electrode E1 may be physically and electrically connected to the drain electrode DE through an opening in the second insulating layer IL2. Accordingly, the first electrode E1 may receive the output current to be transmitted from the drain electrode DE to the light-emitting layer EML.

A pixel defining layer PDL and a spacer SPC may be disposed on the first electrode E1 and the second insulating layer IL2. A pixel opening OP1 that overlaps at least a portion of the first electrode E1 may be defined in the pixel defining layer PDL. At this time, the pixel opening OP1 may overlap the center of the first electrode E1 and may not overlap the edge of the first electrode E1. Accordingly, the size of the pixel opening OP1 may be smaller than the size of the first electrode E1. The pixel defining layer PDL may define the formation location of the light-emitting layer EML so that the light-emitting layer EML may be disposed on the exposed portion of the upper surface of the first electrode E1. The pixel opening OP1 may define the light-emitting region of each pixel.

The pixel defining layer PDL and the spacer SPC may each be an organic insulating layer that includes one or more materials selected from the group including polyimide, polyamide, acrylic resin, benzocyclobutene, and phenol resin, and in an embodiment, the pixel defining layer PDL may be formed as a black pixel defining layer BPDL including or consisting of a black pigment.

The light-emitting layer EML may be disposed in the pixel opening OP1 partitioned by the pixel defining layer PDL. The light-emitting layer EML may include or consist of organics that emit light such as red, green, and blue light. The light-emitting layer EML, which emits red, green, and blue light, may include or consist of low-molecular or high-molecular organic materials. In FIG. 5, the light-emitting layer EML is shown as a single layer, but in reality, auxiliary layers such as an electron injection layer, an electron transport layer, a hole transport layer, and a hole injection layer may also be included above and below the light-emitting layer EML, a hole injection layer and a hole transport layer may be disposed at the bottom of the light-emitting layer EML, and the electron transport layer and the electron injection layer may be disposed at the top of the light-emitting layer EML.

The second electrode E2 may be disposed on the pixel defining layer PDL and the light-emitting layer EML. The second electrode E2 is also referred to as the cathode electrode and may be formed as a transparent conductive layer that includes materials such as ITO, IZO, IGZO, and ITZO. Additionally, the second electrode E2 may have translucent characteristics, and in this case, it may form a microcavity together with the first electrode E1. According to the microcavity structure, the distance and characteristics between both electrodes allow light of a predetermined wavelength to be emitted upward, and as a result, red, green, or blue colors may be displayed.

The first electrode E1, the light-emitting layer EML, and the second electrode E2 may form one light-emitting diode ED.

The encapsulation layer ENC may be disposed on the second electrode E2. The encapsulation layer ENC may include at least one inorganic layer and at least one organic layer. In this embodiment, the encapsulation layer ENC may include a first inorganic encapsulation layer EIL1, an organic encapsulation layer EOL, and a second inorganic encapsulation layer EIL2. However, this is only an illustrative embodiment, and the number of inorganic and organic films constituting the encapsulation layer ENC may be changed in various ways.

A lower sensing electrode portion MTL1 and an upper sensing electrode portion MTL2 may be disposed on the encapsulation layer ENC. This specification limits the configuration in which the lower sensing electrode portion MTL1 is disposed directly above the encapsulation layer ENC, but is not limited to this and the lower sensing insulating layer may be disposed between the encapsulation layer ENC and the lower sensing electrode portion MTL1.

The lower sensing electrode portion MTL1 may include at least one of the plurality of sensing electrodes 520 and 540 described above, the first sensing electrode connecting portion 521, and the second sensing electrode connection portion 541. The upper sensing electrode portion MTL2 may include the remainder of the plurality of sensing electrodes 520 and 540, the first sensing electrode connection portion 521, and the second sensing electrode connection portion 541 described above. In an embodiment, the lower sensing electrode portion MTL1 includes a plurality of sensing electrodes 520 and 540 and a first sensing electrode connection portion 521, and the upper sensing electrode portion MTL2 includes a second sensing electrode connection portion 541. In an alternative embodiment, the lower sensing electrode portion MTL1 includes a second sensing electrode connection portion 541, and the upper sensing electrode portion MTL2 includes a plurality of sensing electrodes 520 and 540, and a first sensing electrode connection portion 521 may be included. It is not limited to this, and may be modified into various embodiments. This specification describes an embodiment in which the lower sensing electrode portion MTL1 includes a sensing electrode connection portion.

The first sensing insulating layer TL1 may be disposed on the encapsulation layer ENC and the lower sensing electrode portion MTL1. The first sensing insulating layer TL1 may include an inorganic insulating material or an organic insulating material. The inorganic insulating material may include at least one of a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, or a silicon oxynitride. The organic insulating material may include at least one of acrylic resin, methacrylic resin, polyisoprene, vinyl resin, epoxy resin, urethane resin, cellulose resin, and perylene resin.

An upper sensing electrode portion MTL2 may be disposed on the first sensing insulating layer TL1. As described above, the upper sensing electrode portion MTL2 may include at least one of a plurality of sensing electrodes 520 and 540, a first sensing electrode connection portion 521, and a second sensing electrode connection portion 541. The upper sensing electrode portion MTL2 in an embodiment may include a plurality of sensing electrodes 520 and 540 and a first sensing electrode connection portion 521.

The upper sensing electrode portion MTL2 may be electrically connected to the lower sensing electrode portion MTL1 through a contact hole defined in the first sensing insulating layer TL1.

The display device in an embodiment may further include a reflective layer MTL3 disposed in the same layer as at least one of the lower sensing electrode portion MTL1 and the upper sensing electrode portion MTL2. FIG. 6 shows an embodiment in which the reflective layer MTL3 is disposed in the same layer as the upper sensing electrode portion MTL2. In this case, the reflective layer MTL3 may be formed in the same process as the upper sensing electrode portion MTL2 and may include the same material as each other. The reflective layer MTL3 may be disposed on the first sensing insulating layer TL1. The reflective layer MTL3 may overlap the light-emitting layer EML. In particular, the reflective layer MTL3 may overlap the light-emitting region of the corresponding pixel, that is, the area of the pixel opening OP1. One reflective layer MTL3 may be disposed in one light-emitting region of each pixel, but the disclosure is not limited to this.

The reflective layer MTL3 may include a metal or metal alloy such as copper (Cu), molybdenum (Mo), aluminum (Al), silver (Ag), chromium (Cr), tantalum (Ta), and titanium (Ti). The reflective layer MTL3 may consist of a single layer or multiple layers. An etching process may be performed on the first sensing insulating layer TL1 to define a contact hole CNT for electrically connecting the lower sensing electrode portion MTL1 and the upper sensing electrode portion MTL2. In the etching process, a recess area RC may be defined in an area overlapping the reflective layer MTL3. The recess area RC may have a recessed shape from the flat upper surface of the first sensing insulating layer TL1 toward the substrate SUB. The recess area RC may be recessed from the upper surface of the first sensing insulating layer TL1 to a height equal to the height of the contact hole CNT. Depending on the embodiment, the depth of the recess area RC in the third direction DR3 may be adjusted by exposing the position where the recess area RC is to be formed using a halftone mask. In an embodiment, the depth of the third direction DR3 of the recess area RC may be the same as the thickness of the first detection insulating layer TL1, so that the recess area RC may be formed up to an upper surface of the encapsulation layer ENC or the lower detection insulating layer.

Depending on the embodiment, the recess area RC may be recessed deeper from the upper surface of the first sensing insulating layer TL1 toward the substrate SUB than the height of the contact hole CNT. The encapsulation layer ENC may include the recess area RC. An etching process may be additionally performed to form the recess area RC. Depending on the embodiment, the recess area RC and the contact hole CNT may be formed through separate processes.

A plurality of the recess areas RC may be formed in the first sensing insulating layer TL1 of the light-emitting region, an area corresponding to each light-emitting diode ED of each pixel. The plurality of recess areas RC disposed in each light-emitting region may have different heights from the top surface of the first sensing insulating layer TL1 or may have similar or identical heights.

The reflective layer MTL3 may have a shape corresponding to the shape of the first sensing insulating layer TL1 that contacts the reflective layer MTL3. Each reflective layer MTL3 may have a plurality of concave portions CP that are recessed in a cross-sectional view along the recess areas RC of the first sensing insulating layer TL1. The concave portion CP may have a curve in a cross-sectional view. Additionally, the lower surface of the reflective layer MTL3 may have a concavo-convex shape in a cross-sectional view.

External light L2 incident on the light-emitting region may be reflected by structures (e.g., first electrode E1 or second electrode E2) under the reflective layer MTL3. The external light L2 reflected by the structures under the reflective layer MTL3 may be reflected from the lower surface of the reflective layer MTL3 toward the structures under the reflective layer. The external light L2 reflected by the structures under the reflective layer MTL3 may be reflected back to the outside of the display device by the structures under the reflective layer MTL3. That is, the reflective layer MTL3 may reduce external light reflection by allowing the external light L2 reflected by structures under the reflective layer MTL3 to be reflected again. External light L2 reflected from structures below the reflective layer MTL3 may be reflected several times by the reflective layer MTL3.

Light L3 emitted from the light-emitting layer EML may be reflected from the lower surface of the reflective layer MTL3 toward structures (e.g., the first electrode E1 or the second electrode E2) under the reflective layer MTL3. The light L3 reflected by the structures under the reflective layer MTL3 may be reflected back to the outside of the display device by the structures under the reflective layer MTL3. Accordingly, the recycling efficiency of the light L3 emitted from the light-emitting layer EML may be improved. That is, light efficiency may be improved. The light L3 emitted from the light-emitting layer EML may be reflected several times in the reflective layer MTL3, but according to this embodiment, the lower surface of the reflective layer MTL3 has a concavo-convex structure, so the number of reflections may be reduced compared to a flat surface, and may reduce the loss of light due to reflection.

A second sensing insulating layer TL2 may be disposed on the upper sensing electrode MTL2 and the reflective layer MTL3. The second sensing insulating layer TL2 may include an inorganic insulating material or an organic insulating material. The inorganic insulating material may include at least one of a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, or a silicon oxynitride. The organic insulating material may include at least one of acrylic resin, methacrylic resin, polyisoprene, vinyl resin, epoxy resin, urethane resin, cellulose resin, and perylene resin.

Light-blocking layers BM1 and BM2 and a color filter CF may be disposed on the second sensing insulating layer TL2.

Light-blocking layers BM1 and BM2 in an embodiment may include a first light-blocking layer BM1 and a second light-blocking layer BM2. The first light-blocking layer BM1 may be disposed to overlap the lower sensing electrode portion MTL1 and the upper sensing electrode portion MTL2, and may be spaced apart from the first electrode E1 without overlapping. This is to ensure that the first electrode E1 and the light-emitting layer EML capable of displaying an image are not obscured by the first light-blocking layer BM1, the lower sensing electrode portion MTL1, and the upper sensing electrode portion MTL2.

The second light-blocking layer BM2 may overlap the reflective layer MTL3. The second light-blocking layer BM2 may have a shape that completely covers the reflective layer MTL3. The second light-blocking layer BM2 may overlap the first electrode E1 and the light-emitting layer EML. The second light-blocking layer BM2 may absorb external light L1 incident on the light-emitting region and reduce external light reflection.

A color filter CF may be disposed on the light-blocking layers BM1 and BM2 and the second sensing insulating layer TL2. The color filter CF includes a red color filter that transmits red light, a green color filter that transmits green light, and a blue color filter that transmits blue light.

Each color filter CF may be disposed to overlap the first electrode E1 of the light-emitting diode in a plan view. Since the light emitted from the light-emitting layer EML may change to a corresponding color as it passes through a color filter, all light emitted from the light-emitting layer EML may have the same color. However, the light-emitting layer EML emits light of different colors, and the displayed color may be strengthened by passing it through a color filter of the same color.

The first light-blocking layer BM1 may be disposed between each color filter CF. Depending on the embodiment, the color filter CF may be replaced with a color conversion layer or may further include a color conversion layer. The color conversion layer may include quantum dots.

A planarization layer TL3 covering the color filter CF is disposed on the color filter CF. The planarization layer TL3 is used to planarize the upper surface of the light-emitting display panel and may be a transparent organic insulating layer including or consisting of one or more materials selected from the group including polyimide, polyamide, acrylic resin, benzocyclobutene, and phenol resin.

Depending on the embodiment, a relatively low refractive index layer and an additional planarization layer may be further disposed on the planarization layer TL3 to improve front visibility and light output efficiency of the display panel. Light may be refracted and emitted toward the front by an additional flattening layer with a relatively low refractive layer and a relatively high refractive characteristic. In this case, depending on the embodiment, the planarization layer TL3 may be omitted and a relatively low refractive index layer and an additional planarization layer may be disposed directly above the color filter CF.

In this embodiment, a polarizing plate is not included on top of the planarization layer TL3. The polarizer may prevent display quality from deteriorating when external light is incident and reflected by the first electrode E1 or the sidewall of the pixel opening of the pixel defining layer PDL, which is visible to the user. However, the polarizer has the disadvantage of consuming more power to display a predetermined luminance by not only reducing the reflection of external light but also reducing the light emitted from the light-emitting layer EML. In order to reduce power consumption, the light-emitting display device of this embodiment may not include a polarizer. Additionally, the weight and/or thickness of the display device may be reduced.

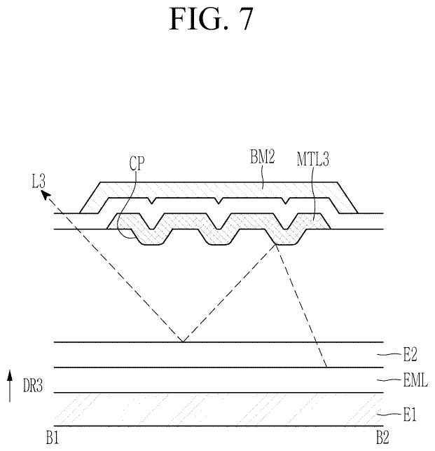

Below, with reference to FIG. 7, the path of light L3 emitted from the light-emitting layer EML will be described. FIG. 7 is a schematic cross-sectional view showing a portion of FIG. 6.

Referring to FIG. 7, the light L3 emitted from the light-emitting layer EML may be reflected toward the structures below the reflective layer MTL3 (e.g., the first electrode E1 or the second electrode E2) from the lower surface of the reflective layer MTL3.

The light L3 reflected by the structures under the reflective layer MTL3 may be reflected back to the outside of the display device by the structures under the reflective layer MTL3.

In an embodiment, the light L3 emitted from the light-emitting layer EML is reflected on the lower surface of the concavo-convex structure including a plurality of concave portions CP of the reflective layer MTL3, so that the reflection angle may vary. In this case, the light L3 may be diffusely reflected on the lower surface of the reflective layer MTL3. Accordingly, when the light L3 is reflected from the lower surface of the reflective layer MTL3, the number of reflections may be smaller than when the light L3 is reflected from a flat surface. As the number of reflections of the light L3 decreases, the decrease in the intensity of the light L3 exiting the display device may be reduced. Accordingly, the recycling efficiency of light may be improved, thereby improving the light efficiency of the display device.

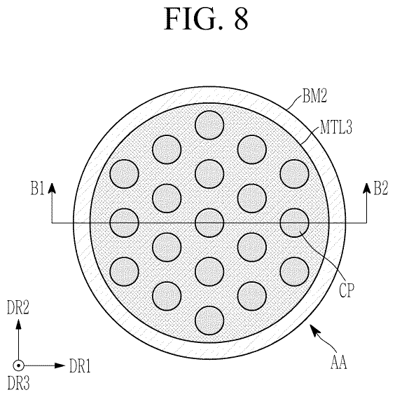

Hereinafter, with reference to FIG. 8 along with the previously described drawings, the second light-blocking layer BM2, the reflective layer MTL3, and the concave portion CP in an embodiment will be described. FIG. 8 is a schematic plan view showing a portion AA of a pixel.

Referring to FIG. 8, the second light-blocking layer BM2 may overlap the reflective layer MTL3, and MTL3 may be disposed within an edge of the second light-blocking layer BM2. The reflective layer MTL3 may overlap a plurality of recess areas RC of the first sensing insulating layer TL1 and may include a concave portion CP corresponding to each recess area RC. The second light-blocking layer BM2 may have a circular, oval, or polygonal shape in a plan view. Additionally, the reflective layer MTL3 may have a circular, oval, or polygonal shape in a plan view.

The planar shape of the recess area RC or the concave portion CP may be circular shape with a center. Referring to FIG. 8, the distances between the centers of recess areas RC next to each other or concave portions CP next to each other may be constant.

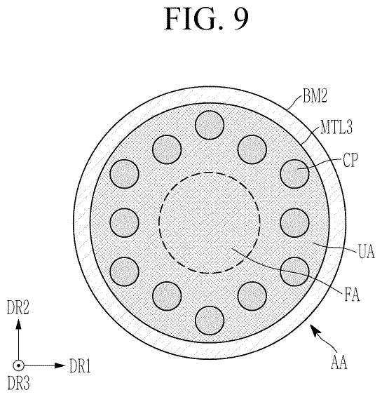

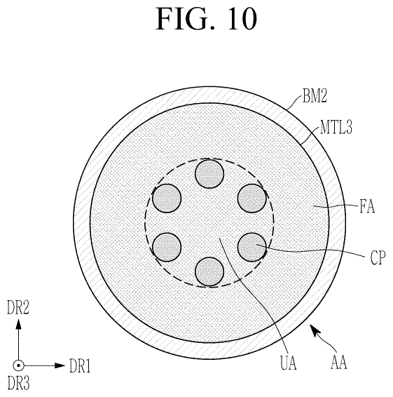

Hereinafter, with reference to FIGS. 9 and 10, the shapes of the second light-blocking layer BM2, the reflective layer MTL3, and the concave portion CP in an embodiment will be described. FIG. 9 and FIG. 10 are schematic plan views showing a portion AA of a pixel.

Referring to FIGS. 9 and 10, the reflective layer MTL3 may include an uneven portion UA and a flat portion FA in a plan view. The uneven portion UA may include a plurality of concave portions CP, and the flat portion FA may not include a concave portion CP.

Referring to FIG. 9, the plurality of concave portions CP may be disposed close to the edge of the reflective layer MTL3. The uneven portion UA may be disposed closer to the edge of the reflective layer MTL3 than the flat portion FA. The uneven portion UA may be disposed in an outer area of the reflective layer MTL3. Here, the outer area of the reflective layer MTL3 may be an area closer to the edge than the center of the reflective layer MTL3 in a plan view.

Referring to FIG. 10, a plurality of concave portions CP may be disposed in an inner area of the reflective layer MTL3. The uneven portion UA of the reflective layer MTL3 may be disposed in an inner area of the reflective layer. At this time, the inner area of the reflective layer MTL3 may be an area closer to the center than the edge of the reflective layer MTL3 in a plan view.

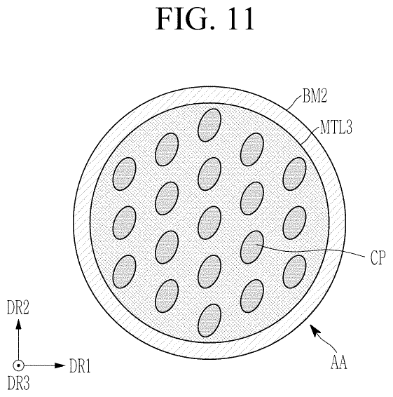

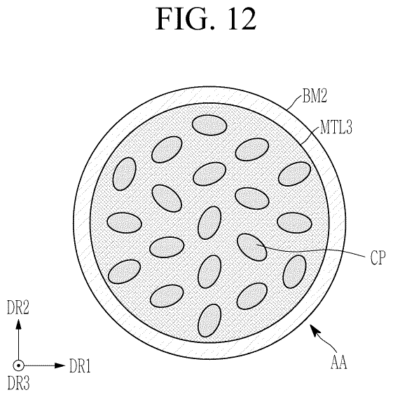

Hereinafter, with reference to FIGS. 11 and 12, the second light-blocking layer BM2, the reflective layer MTL3, and the concave portion CP in an embodiment will be described. FIG. 11 and FIG. 12 are schematic plan views showing a portion AA of a pixel.

Referring to FIGS. 11 and 12, the concave portion CP may be an oval shape with a major axis in a plan view. Referring to FIG. 11, directions of the major axes of the plurality of concave portions CP included in each reflective layer MTL3 may be constant. Referring to FIG. 12, directions of two or more major axes of the plurality of concave portions CP included in each reflective layer MTL3 may not be constant.

Additionally, the distances between the plurality of concave portions CP included in each reflective layer MTL3 may be constant. Depending on the embodiment, the distances between the plurality of concave portions CP included in each reflective layer MTL3 may not be constant for at least some of the concave portions CP.

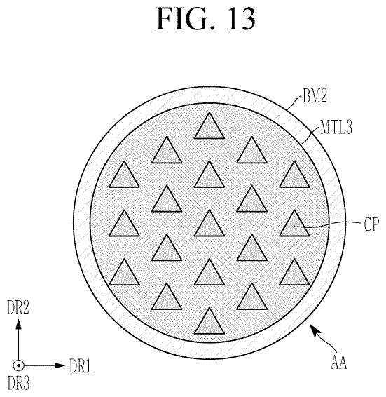

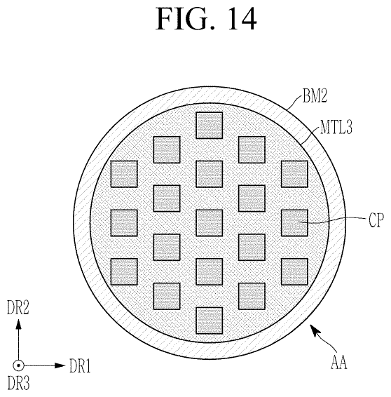

Hereinafter, with reference to FIGS. 13 and 14, the second light-blocking layer BM2, the reflective layer MTL3, and the concave portion CP in an embodiment will be described. FIG. 13 and FIG. 14 are schematic plan views showing a portion AA of a pixel.

Referring to FIG. 13, the concave portion CP in an embodiment may be triangular shape in a plan view. Referring to FIG. 14, the concave portion CP in an embodiment may be square shape in a plan view.

Without being limited thereto, the concave portion CP may be a polygonal shape having a center of gravity in a plan view. Hereinafter, “center of gravity” may be also referred to as “center”. The distances between the centers of the plurality of concave portions CP included in each reflective layer MTL3 may be constant. Depending on the embodiment, the distances between the centers of the plurality of concave portions CP included in each reflective layer MTL3 may not be constant.

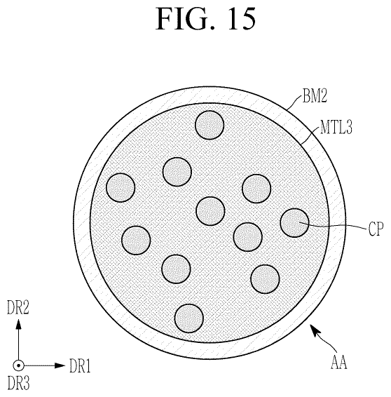

FIG. 15 is a plan view showing an embodiment of a portion of a pixel.

Referring to FIG. 15 along with the previously described drawings, for at least some of the plurality of concave portions CP of each reflective layer MTL3, the distances between the centers of concave portions CP next to each other may be different. FIG. 15 shows an example where the planar shape of the concave portion CP is circular shape, but it is not limited to this, and even when the planar shape of the concave portion CP is of various shapes such as oval and various polygonal shapes, the distances between centers or the distances between concave portions CP next to each other may not be constant.

Depending on the embodiment, the plurality of concave portions CP included in each reflective layer MTL3 may include at least two or more concave portions CP having different shapes and/or areas in a plan view.

Although the embodiments of the disclosure have been described in detail above, the scope of the disclosure is not limited thereto, and various modifications and improvements made by those skilled in the art using the basic concepts of the disclosure defined in the following claims are also possible.

What is claimed is:

1. A display device comprising:
a substrate;
a first electrode disposed on the substrate;
a pixel defining layer in which a pixel opening is defined on the first electrode;
a light-emitting layer disposed in the pixel opening;
a second electrode disposed on the light-emitting layer;
an encapsulation layer disposed on the second electrode;
a sensing electrode portion and a reflective layer disposed on the encapsulation layer;
a first light-blocking layer overlapping the sensing electrode portion; and
a second light-blocking layer overlapping the reflective layer,
wherein the reflective layer includes a plurality of concave portions disposed in an area overlapping the second light-blocking layer.

2. The display device of claim 1, further comprising
a sensing insulating layer disposed between the reflective layer and the encapsulation layer,
wherein the sensing insulating layer includes a plurality of recess areas corresponding to the plurality of concave portions.

3. The display device of claim 2, wherein
the reflective layer contacts an upper surface of the sensing insulating layer.

4. The display device of claim 2, wherein
the sensing electrode portion includes a first electrode layer and a second electrode layer that are disposed in different conductive layers from each other, and
the sensing insulating layer includes a portion disposed between the first electrode layer and the second electrode layer.

5. The display device of claim 1, wherein
at least some of the plurality of concave portions have a circular shape in a plan view.

6. The display device of claim 1, wherein
at least some of the plurality of concave portions have an oval shape with a major axis in a plan view.

7. The display device of claim 6, wherein
directions of major axes of the plurality of concave portions are identical to each other.

8. The display device of claim 6, wherein
directions of major axes of two or more of the plurality of concave portions are different from each other.

9. The display device of claim 1, wherein
at least some of the plurality of concave portions have polygonal shape in a plan view.

10. The display device of claim 1, wherein
distances between centers of concave portions next to each other among the plurality of concave portions are constant.

11. The display device of claim 1, wherein
for at least some of the plurality of concave portions, distances between centers of concave portions next to each other among the plurality of concave portions are not constant.

12. The display device of claim 1, wherein
at least some of the plurality of concave portions are disposed in an outer area of the reflective layer.

13. The display device of claim 1, wherein
at least some of the plurality of concave portions are disposed in an inner area of the reflective layer.

14. The display device of claim 1, wherein
a concave portion of the plurality of concave portions has a curve in a cross-sectional view.

15. A display device comprising:
a substrate;
a first electrode disposed on the substrate;
a pixel defining layer in which a pixel opening overlapping the first electrode is defined;
a light-emitting layer disposed in the pixel opening;
a second electrode disposed on the light-emitting layer;
an encapsulation layer disposed on the second electrode;
a sensing electrode portion and a reflective layer disposed on the encapsulation layer;
a first light-blocking layer overlapping the sensing electrode portion; and
a second light-blocking layer overlapping the reflective layer,
wherein the reflective layer includes an uneven portion and a flat portion in an area overlapping the second light-blocking layer.

16. The display device of claim 15, wherein
the uneven portion includes a plurality of concave portions.

17. The display device of claim 16, wherein
a planar shape of the plurality of concave portions is at least one of a circular shape, an oval shape, a triangle shape, a square shape, and a pentagon shape with a center.

18. The display device of claim 17, wherein
distances between centers of concave portions next to each other among the plurality of concave portions are constant.

19. The display device of claim 15, wherein
the uneven portion is disposed in an outer area of the reflective layer.

20. The display device of claim 15, wherein
the uneven portion is disposed in an inner area of the reflective layer.

21. An electronic device comprising a display device,
the display device comprising:
a substrate;
a first electrode disposed on the substrate;
a pixel defining layer in which a pixel opening is defined on the first electrode;
a light-emitting layer disposed in the pixel opening;
a second electrode disposed on the light-emitting layer;
an encapsulation layer disposed on the second electrode;
a sensing electrode portion and a reflective layer disposed on the encapsulation layer;
a first light-blocking layer overlapping the sensing electrode portion; and
a second light-blocking layer overlapping the reflective layer,
wherein the reflective layer includes a plurality of concave portions disposed in an area overlapping the second light-blocking layer.

22. The electronic device of claim 21, wherein
the display device further comprising:
a sensing insulating layer disposed between the reflective layer and the encapsulation layer,
wherein the sensing insulating layer includes a plurality of recess areas corresponding to the plurality of concave portions.
